(19) United States
(12) Patent Application Publication
(10) Pub. No.: US 2009/0160042 A1
(43) Pub. Date: Jun. 25, 2009

(54) Managed Memory Component

(75) Inventors: James Douglas Wehrly, JR., Austin, TX (US); Leland Szewerenko, Austin, TX (US); David L. Roper, Austin, TX (US)

Correspondence Address: FISH & RICHARDSON P.C., P.O BOX 1022, Minneapolis, MN, 55440-1022, US

(73) Assignee: Entorian Technologies, LP

(21) Appl. No.: 12/395,984

(22) Filed: Mar. 2, 2009

Related U.S. Application Data
(63) Continuation of application No. 11/447,590, filed on Jun. 7, 2006.
Application No. 11/447,590 is a continuation-in-part of application No. 11/332,307, filed on Jan. 17, 2006.
Application No. 11/332,307 is a continuation-in-part of application No. 11/436,946, filed on May 18, 2006, now Pat. No. 7,508,069.

(51) Int. Cl. H01L 23/00

(52) U.S. Cl. 257/686; 257/E23.002

(57) ABSTRACT

A system and method for combining a leaded package IC and a semiconductor die using a flex circuitry. The leaded packaged IC is disposed along an obverse side of a flex circuit. In a preferred embodiment, the lower surface of the body of the leaded packaged IC contacts the surface of the flex circuitry. The semiconductor die is disposed beneath the leaded package IC and, in preferred embodiments, disposed in a window that passes through at least a part of the flex circuitry and is attached to a conductive layer of the flex circuitry. In other embodiments, the semiconductor die is attached to the body of the leaded packaged IC. The flex circuitry preferably employs at least two conductive layers and, in preferred embodiments, the leaded packaged IC is connected to the flex circuitry at one layer while the semiconductor die is connected to the flex circuitry at the other conductive layer. In preferred modules, the leaded packaged IC is preferably a flash memory device and the semiconductor die is preferably a controller.

### RELATED APPLICATIONS

The present application is a continuation of U.S. application Ser. No. 11/447,590, filed Jun. 7, 2006, which is a continuation-in-part of U.S. patent application Ser. No. 11/330,307, filed Jan. 11, 2006, currently pending, and a continuation-in-part of U.S. patent application Ser. No. 11/436,946, filed May 18, 2006, currently pending, all of which applications are hereby incorporated by reference.

### TECHNICAL FIELD

This invention relates to integrated circuit modules and, in particular, to integrated circuit modules that provide memory and controller in a compact footprint module.

### BACKGROUND

A variety of systems and techniques are known for combining integrated circuits in compact modules. Some techniques are suitable for combining packaged integrated circuits while other techniques are suitable for combining semiconductor die. Many systems and techniques employ flex circuitry as a connector between packaged integrated circuits in, for example, stacks of packaged leaded or chip-scale integrated circuits. Other techniques employ flex circuitry to “package” semiconductor die and function as a substitute for packaging.

Within the group of technologies that stack packaged integrated circuits, some techniques are devised for stacking chip-scale packaged devices (CSPs) while other systems and methods are better directed to leaded packages such as those that exhibit a set of leads extending from at least one lateral side of a typically rectangular package.

Integrated circuit devices (ICs) are packaged in both chip-scale (CSP) and leaded packages. However, techniques for stacking CSP devices are typically not optimum for stacking leaded devices, just as techniques for leaded device stacking are typically not suitable for CSP devices. Few technologies are, however, directed toward combining packaged integrated circuits with semiconductor die.

Although CSP devices are gaining market share, in many areas, integrated circuits continue to be packaged in high volumes in leaded packages. For example, the well-known flash memory integrated circuit is typically packaged in a leaded package with fine-pitched leads emergent from one or both sides of the package. A common package for flash memory is the thin small outline package commonly known as the TSOP typified by leads emergent from one or more (typically a pair of opposite sides) lateral sides of the package.

Flash memory devices are gaining wide use in a variety of applications. Typically employed with a controller for protocol adaption, flash memory is employed in solid state memory storage applications that are supplanting disk drive technologies. However, when flash memory is employed with controller logic, the application footprint typically expands to accommodate the multiple devices required to provide a module that is readily compatible with most memory subsystem interface requirements. Consequently, what is needed is a memory module that includes a controller logic and flash memory storage without substantial increases in footprint or thickness.

### SUMMARY OF THE INVENTION

The present invention provides a system and method for combining a leaded package IC and a semiconductor die using a flex circuitry. The leaded packaged IC is disposed along an obverse side of a flex circuit. In a preferred embodiment, the lower surface of the body of the leaded packaged IC contacts the surface of the flex circuitry. In preferred embodiments, the semiconductor die is disposed in a window that passes through at least a part of the flex circuitry and the die is attached to a conductive layer of the flex circuitry. In other embodiments, the semiconductor die is attached to the body of the leaded packaged IC. The flex circuitry preferably employs at least two conductive layers and the leaded packaged IC is preferably connected to the flex circuitry at one layer while the semiconductor die is electrically connected to the flex circuitry at another conductive layer. In preferred modules, the leaded packaged IC is preferably a flash memory device and the semiconductor die is preferably a controller.

### BRIEF DESCRIPTION OF THE DRAWINGS

FIG. 1 is a side view of an exemplar module devised in accordance with a preferred embodiment of the present invention.

FIG. 2 is an enlarged side view of the area marked “A” in FIG. 1 of a module devised in accordance with a preferred embodiment of the present invention.

FIG. 3 is a perspective view of a module devised in accordance with an embodiment of the present invention.

FIG. 4 depicts a cross-sectional view of a circuit module taken along line C-C of FIG. 3 and in accordance with an embodiment of the present invention illustrating the disposition of a semiconductor die relative to flex circuitry and a leaded packaged IC.

FIG. 5 depicts a cross-sectional view of a circuit module taken along line C-C of FIG. 3 and in accordance with an alternative embodiment of the present invention illustrating the disposition of a semiconductor die relative to flex circuitry and a leaded packaged IC.

FIG. 6 depicts a cross-sectional view of a circuit module taken along line C-C of FIG. 3 and in accordance with another alternative embodiment of the present invention illustrating the disposition of a semiconductor die relative to flex circuitry and a leaded packaged IC.

FIG. 7 depicts a cross-sectional view of a circuit module taken along line C-C of FIG. 3 and in accordance with another alternative embodiment of the present invention illustrating attaching the semiconductor die to the body of the leaded packaged IC.

FIG. 8 depicts a cross-sectional view of a circuit module in accordance with another alternative embodiment of the present invention illustrating the disposition of a semiconductor die relative to flex circuitry and a leaded packaged IC in which the body leaded packaged IC is not in contact with the flex circuitry.

FIG. 9 depicts a cross-sectional view of a circuit module in accordance with another alternative embodiment of the present invention illustrating the disposition of a semiconductor die relative to flex circuitry and a leaded packaged IC in which the body leaded packaged IC is not in contact with the flex circuitry and the semiconductor die is set into the body of the leaded packaged IC.

FIG. 10 is an enlarged depiction of the attachment of a semiconductor die to a metal layer in flex circuitry in accordance with an embodiment of the present invention.

### DETAILED DESCRIPTION

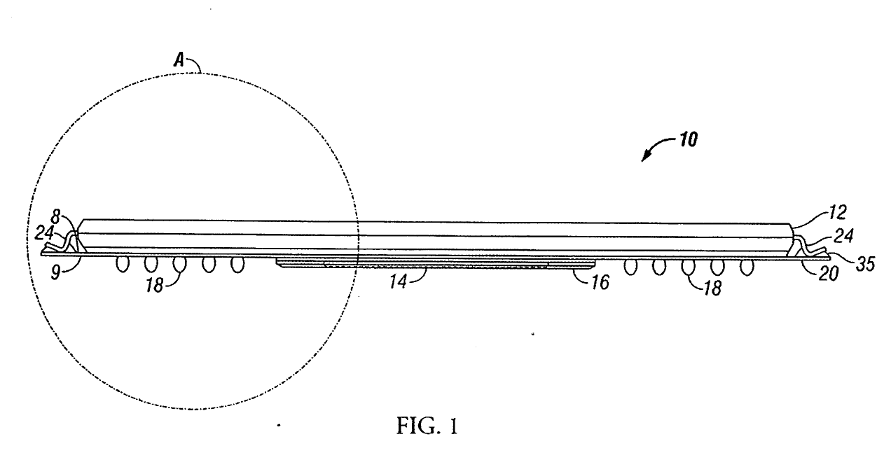

FIG. 1 is a side view of an exemplar module 10 devised in accordance with a preferred embodiment of the present invention. Exemplar module 10 is comprised of leaded packaged IC 12 and semiconductor die 14 each connected to flex circuitry 20. In preferred embodiments, leaded packaged IC 12 is a flash memory device and semiconductor die 14 is a controller. In a preferred embodiment, semiconductor die 14 is covered by an encapsulate 16 as shown. Module contacts 18 are shown arrayed along side 9 of flex circuitry 20 while leaded packaged IC 12 is disposed along side 8 of flex circuitry 20. Flex circuitry 20 is comprised from multiple layers including one or more conductive layers supported by one or more flexible substrate layers and is preferably comprised with two conductive layers although more layers are commensurate with the invention as well. Flex circuitry with one conductive layer could also be devised to be employed with some embodiments of the invention.

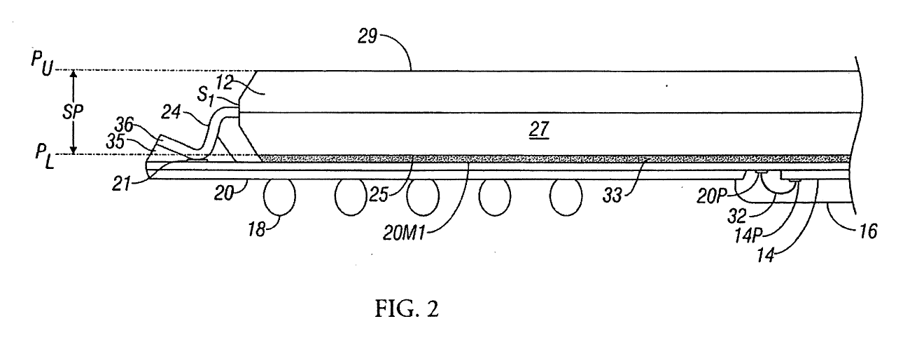

FIG. 2 is an enlarged side view of the area marked “A” in FIG. 1 of a module devised in accordance with a preferred embodiment of the present invention. As shown in FIG. 2, leaded packaged IC 12 has upper side 29 and lower side 25 and is connected to flex circuitry 20 through leads 24 that are connected to leaded IC pads 21 which are, in many but not all embodiments, located along side 8 of flex circuitry 20 as identified in later views. Some embodiments, however, dispose leaded IC pads 21 on side 9 of flex circuitry 20 as will be later shown. As those of skill will recognize, many techniques exist for connecting the leads of leaded packaged IC 12 to leaded pads 21. Such techniques include, as a non-limiting example, use of solder such as solder 35 shown in FIGS. 1 and 2. Other forms of bonding other than solder between leaded IC pads 21 and leads 24 may also be employed (such as brazing, welding, tab bonding, or ultrasonic bonding, just as examples) but soldering techniques arc well understood and adapted for use in large scale manufacturing. Leads 24 typically but not always, exhibit feet 36. Later views will show embodiments in which leads 24 do not exhibit feet 36. Leads 24 may be connected to either or both of the sides of flex circuitry 20 as will be later shown.

Preferably an adhesive 33 is used between body 27 of leaded packaged IC 12 and flex circuit 20. Module contacts 18 are, in the depicted embodiment, balls such as those found in ball grid array (BGA) but other types of module contacts 18 may be employed in embodiments of the present invention.

Body 27 of leaded packaged IC 12 has a lower surface 25 that is in contact with flex circuitry 20. Conductive layer 20M1 is identified in FIG. 2 but it is one of multiple layers from which a flex circuitry is comprised in preferred embodiments. In this disclosure, “contact” between the lower surface 25 of leaded packaged IC 12 and the surface of flex circuit 20 includes not only direct contact between lower surface or side 25 of leaded packaged IC 12 and the flex circuitry but shall include those instances where intermediate materials such as depicted adhesive 33 and/or a thermal media is used between the respective leaded packaged IC and flex circuitry. As shown in FIGS. 1 and 2, leaded packaged IC 12 exhibits lateral sides SI and S2 which, as those of skill will recognize, may be in the character of edges or sides and need not be perpendicular in aspect to the upper and lower surfaces 29 and 25, respectively. Leads 24 are emergent from sides S1 and S2 in the depicted leaded packaged IC 12 but those of skill will note that some leaded packaged ICs may have leads emergent from only one side or more than two sides. In the embodiment depicted in FIG. 2, leads 24 are preferably configured within space SP defined by planes PL, and PU which are defined by lower and upper surfaces 25 and 29, respectively, of the leaded IC to allow the lower surface 25 of the leaded packaged IC 12 to be in contact with the flex circuitry 20 either directly or indirectly through adhesive, for example, when leaded packaged IC 12 is connected to the flex circuitry. Any height of pad 21 can be accommodated by adhesive 33 as those of skill will recognize.

Although there are multiple techniques to realize contact between the lower surface of leaded packaged IC 12 and flex circuitry 20, reconfiguration (e.g., modification, reforming) of the leads may be employed where there is a desire to not modify the flex circuitry to accomplish the result. Higher thicknesses of adhesive will also cause contact to be realized without substantial reconfiguration. However, thick adhesives are not preferred. Reconfiguration is preferably performed before mounting of the leaded IC to flex circuit 20. Those of skill will note that a preferred method for reconfiguration of leads 24, if desired, comprises use of a jig to fix the position of body 27 of the leaded packaged IC and, preferably, support the lead at the point of emergence from the body at sides S1 and S2 before deflection of the respective leads toward the upper plane PU to confine leads 24 to the space between planes PL and PU of the leaded packaged IC. This is because typically, leaded packaged ICs such as TSOPs are configured with leads that extend substantially beyond the lower plane PL. In order for the lower surface 25 of the respective leaded packaged ICs to contact (either directly or through an adhesive or thermal intermediary, for example) the respective surfaces of the flex circuit, the leads 24 may need to be reconfigured. Other configurations of leads 24 may not, however, require or exhibit configurations in which the lead is within space SP and yet lower surface 25 still exhibits contact with flex circuitry 20.

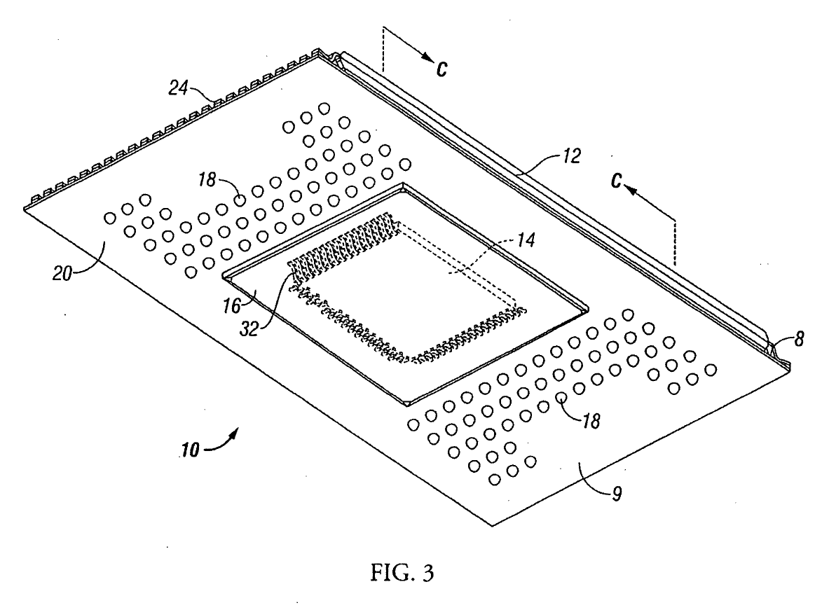

FIG. 3 is a perspective view of a module devised in accordance with an embodiment of the present invention. As depicted, semiconductor die 14 is connected through wire bonds 32 to flex circuit 20. As will be later shown, wire bonds 32 are attached to flex pads 20P of flex circuitry 20. Concurrently, leaded packaged IC 12 is connected to flex circuitry 20 through leads 24. Module contacts 18 and die 14 is shown encapsulated by encapsulate 16. A variety of methods can be employed to effectuate the encapsulation of die 14 and such methods are known to those of skill in the art.

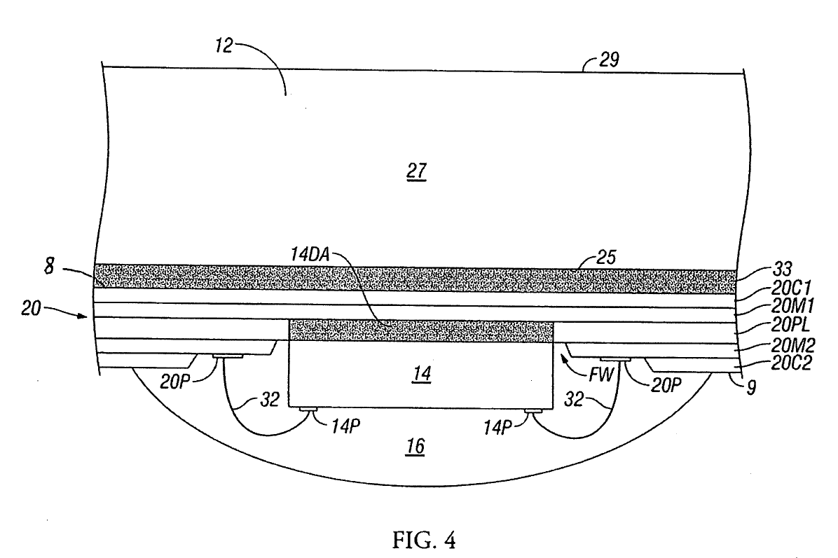

FIG. 4 depicts a cross-sectional view of a part of circuit module 10 in accordance with an embodiment of the present invention illustrating the disposition of semiconductor die 14 relative to flex circuitry 20 and leaded packaged IC 12. Also shown are details on a preferred flex circuitry 20 that exhibits multiple layers including at least two conductive layers identified in FIG. 4 as 20M1 and 20M2 which, in this embodiment, are separated by a polyimide layer 20PL. Conductive layers 20M1 and 20M2 are typically copper that has been plated with emersion nickel gold or emersion nickel silver or organic surface protection where needed. In a preferred embodiment, pads 21 shown earlier are connected to layer 20M1. Optional covercoat 20C1 is shown along with covercoat 20C2 which also is optional. Covercoats on flex circuitry are well understood by those of skill in the art. Conductive layers in flex circuitry are well understood in the art and typically comprise a network of connections that allow interconnections between various components to be realized through the conductive layers.

As shown in FIG. 4, body 27 of leaded packaged IC 12 is in contact with surface 8 of flex circuitry 20 through adhesive 33. As earlier described, a variety of techniques may be implemented to realize contact between lower surface 25 of body 27 of leaded packaged IC 12 and outer surface 8 of flex circuitry 20.

As illustrated, semiconductor die 14 projects into window FW which is accessible from side 9 of flex circuitry 20 and which, in this embodiment, extends through layer 20M2. Although attached to layer 20M1 through die attach 20DA, semiconductor die 14 is electrically connected to layer 20M2 through wire bonds 32 that extend between die pads 14P and flex pads 20P of layer 20M2. Flex pads 20P are depicted in the cross-sectional view of FIG. 4 (and several subsequent Figs.) as rising above layer 20M2 but, as those of skill recognize, these are shown with elevated profile for heuristic purposes and in practice are typically a part of layer 20M2 and would be indistinguishable in this view. Insertion of semiconductor die 14 into window FW assists in reducing the overall profile of module 10 while attachment of semiconductor die 14 to conductive layer 20M1 can function as a heat spreader for semiconductor die 14, depending on the actual layout of layer 20M1 as those of skill will recognize.

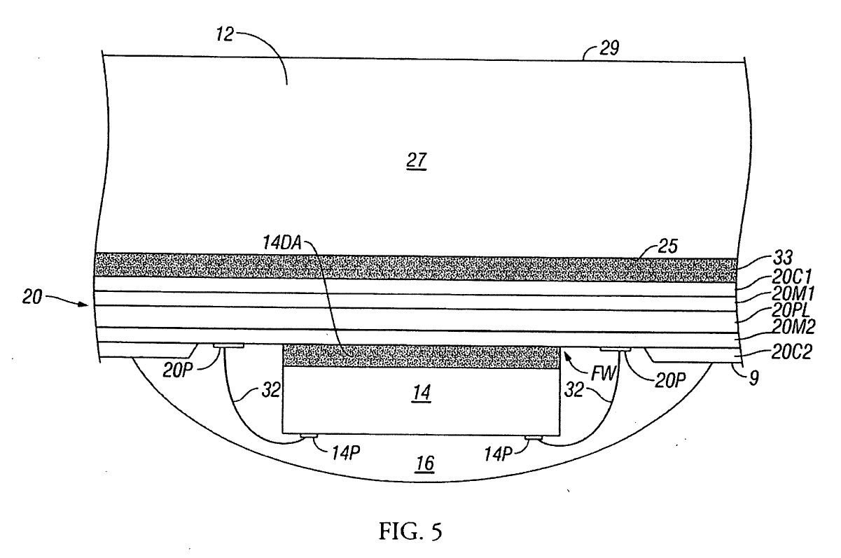

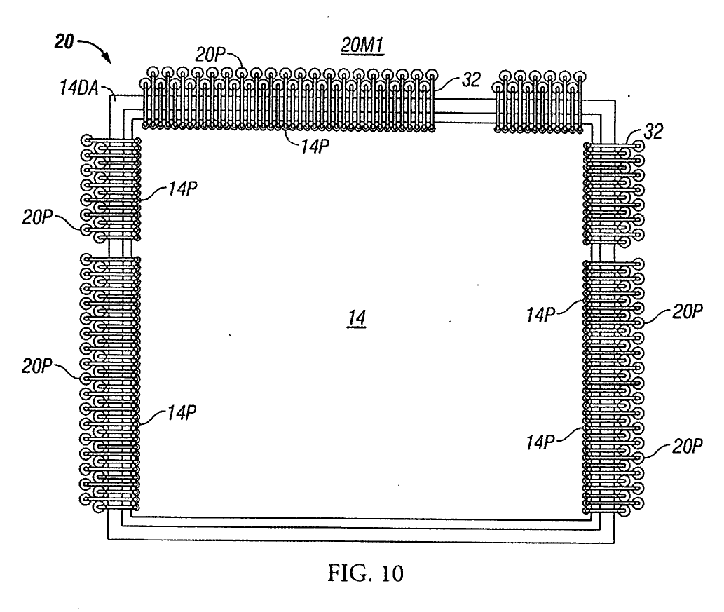

FIG. 5 depicts a cross-sectional view of a circuit module in accordance with an alternative embodiment of the present invention illustrating the disposition of semiconductor die 14 relative to flex circuitry 20 and leaded packaged IC 14. As shown in FIG. 5, as in the embodiment shown in FIG. 4, a portion of flex circuitry 20 has been removed to provide an area for disposition of semiconductor die 14 in flex circuitry 20. In the embodiment shown in FIG. 5, however, semiconductor die 14 passes through window FW which passes through covercoat 20C2 and is attached through die attach 14DA to layer 20M2. Semiconductor die 14 is electrically connected to layer 20M2 through wire bonds 32 between die pads 14P and flex pads 20P. As also shown in FIG. 4, in the embodiment shown in FIG. 10, encapsulate 16 covers the die and wire bond connections.

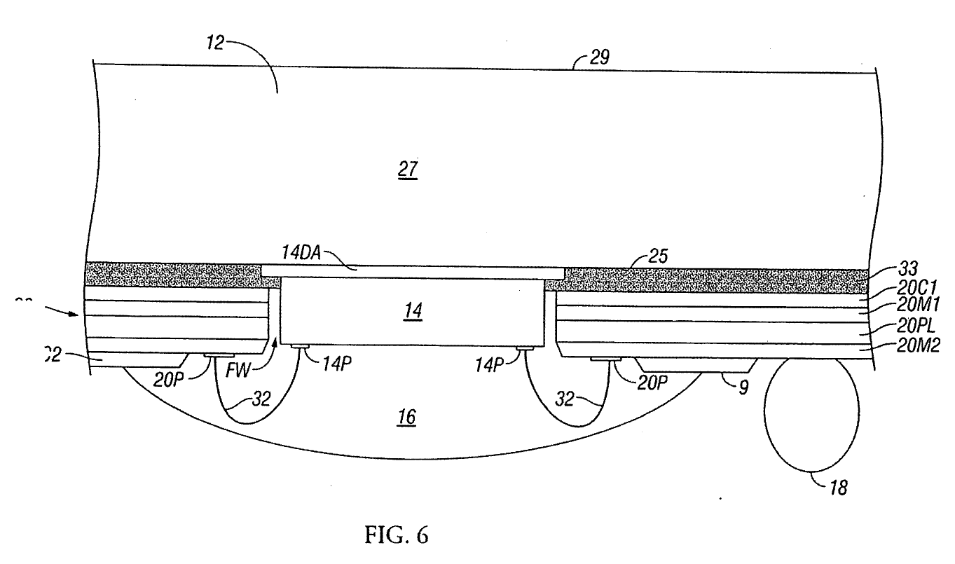

FIG. 6 depicts a cross-sectional view of a circuit module in accordance with another alternative embodiment of the present invention illustrating the disposition of semiconductor die 14 relative to flex circuitry 20 and a leaded packaged IC 12. As shown in FIG. 6, semiconductor die 14 is mounted (with die attach 14DA) to surface 25 of body 27 of leaded packaged IC 12. In this embodiment, window FW passes through all of flex circuit 20 and semiconductor die 14 is disposed in window FW while being attached to body 27 of leaded packaged IC 12 to create a low profile module 10. Semiconductor die 14 is connected to flex circuitry 20 and in particular, to conductive layer 20M2 with wire bonds 32 between die pads 14P and flex pads 20P. Encapsulate 16 covers the die area as shown. FIG. 6 also shows an exemplar module contact 18. As those of skill will recognize, the depiction of module contact 18 is merely representative and the placement, configuration and exact size of the plural module contacts 18 that typically are employed in a module 10 may be varied to fit the needs of the application.

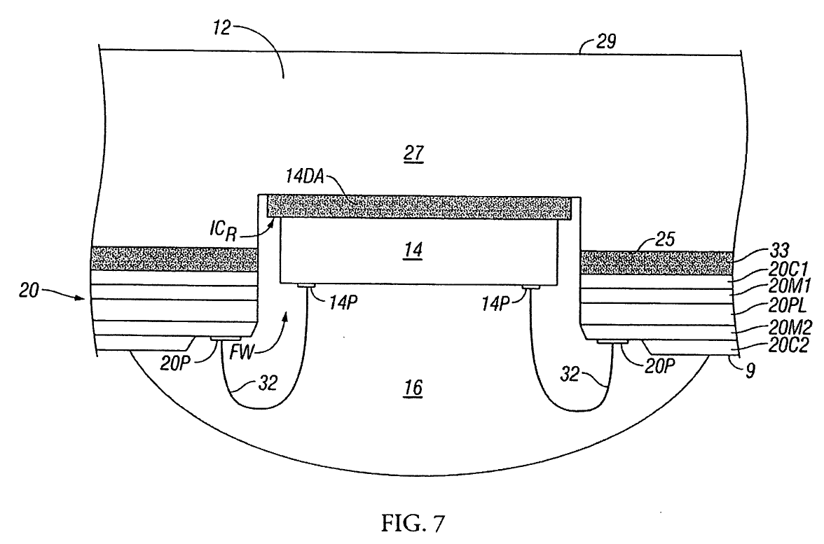

FIG. 7 depicts a cross-sectional view of a circuit module in accordance with another alternative embodiment of the present invention illustrating the disposition of semiconductor die 14 relative to flex circuitry 20 and leaded packaged IC 12. As shown in FIG. 7, body 27 of leaded packaged IC 12 is a cavitated structure that exhibits a cavity or recess IC_{R} into which semiconductor die 14 is disposed for attachment to body 27 of leaded packaged IC 12. As in other embodiments, semiconductor die 14 is connected to flex circuitry 20 and, in particular example, to conductive layer 20M2 but, as those of skill will recognize, a module 10 in accordance with alternative embodiments of the present invention may be devised in which semiconductor die 14 is connected to a different conductive layer of flex circuitry 20 such as 20M1. In other embodiments, a flex circuitry with only one conductive layer could be employed. In some embodiments, both leaded packaged IC 12 and semiconductor die 14 may be connected to the same conductive layer of flex circuitry.

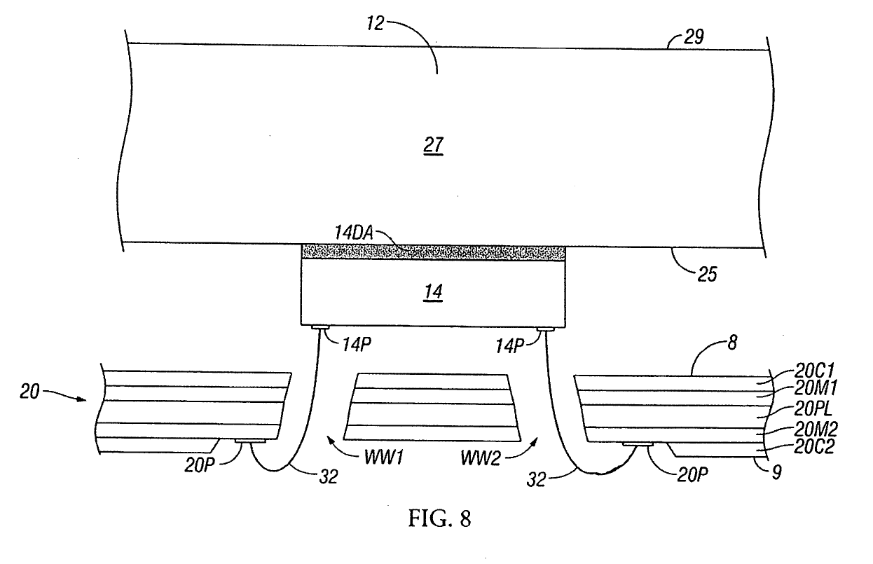

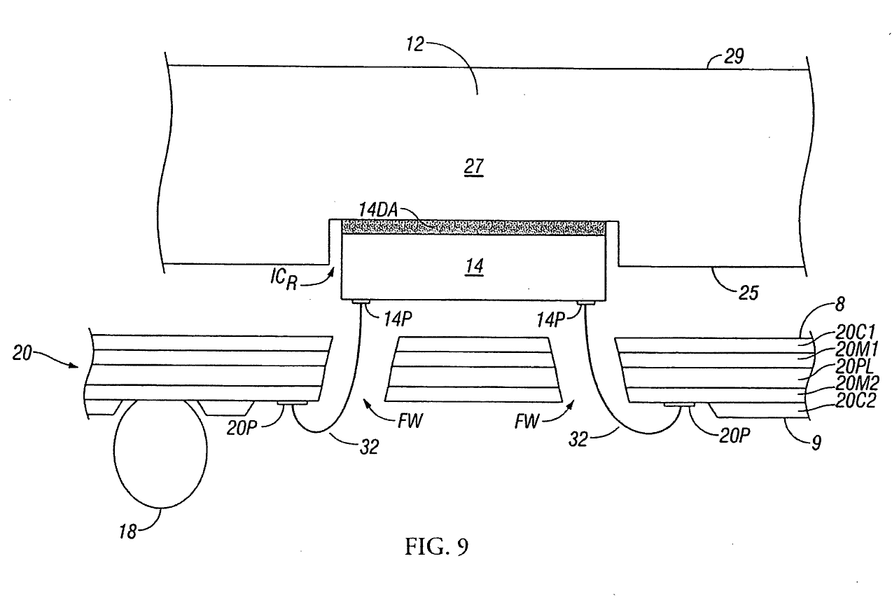

FIGS. 8 and 9 depict alternative embodiments in which there is a gap between leaded packaged IC 12 and flex circuitry 20. In FIG. 8 semiconductor die 14 is attached to surface 25 of body 27 of leaded packaged IC 12 and in FIG. 9, body 27 is cavitated with cavity or recess IC_{R} for recessed disposition of leaded package IC 12. Such embodiments as shown in FIGS. 8 and 9, there will typically be no requirement to reform leads 24 or engage in other lower profile techniques such as those examples earlier illustrated. Each of the embodiments of FIGS. 8 and 9 exhibit wire windows WW1 and WW2 through which wire bonds 32 pass to connect semiconductor die 14 to flex pads 20P and thereby, layer 20M2 as shown or other conductive layers as those of skill will understand.

FIG. 10 depicts semiconductor die 14 and illustrates the plural die pads 14P and plural flex pads 20P and the wire bonds 32 that connect die 14 to flex circuit 20. Die attach 14DA is also shown. As those of skill understand, die attach 14DA is typically an adhesive.

The present invention may also be employed with circuitry other than or in addition to memory such as the flash memory depicted in a number of the present Figs. Other exemplar types of circuitry that may be aggregated in accordance with embodiments of the invention include, just as non-limiting examples, DRAMs, FPGAs, and system stacks that include logic and memory as well as communications or graphics devices. It should be noted, therefore, that the depicted profile for leaded packaged IC 12 is not a limitation and that leaded packaged IC 12 does not have to be a TSOP or TSOP-like and the package employed may have more than one die or leads emergent from one, two, three or all sides of the respective package body. For example, a module 10 in accordance with embodiments of the present invention may employ a leaded packaged IC 12 that has more than one die within the package and may exhibit leads emergent from only one side of the package.

It will be seen by those skilled in the art that many embodiments taking a variety of specific forms and reflecting changes, substitutions, and alternations can be made without departing from the spirit and scope of the invention. Therefore, the described embodiments illustrate but do not restrict the scope of the claims.

1. A circuit module comprising:
flex circuitry having first and second sides, the flex circuitry having a plurality of leaded IC pads and the second side of the flex circuitry having an array of module contacts, the flex circuitry comprising multiple layers including at least first and second conductive layers;
a semiconductor die attached to one of the multiple layers of the flex circuitry and which semiconductor die is electrically connected to one of the first or second conductive layers;
a leaded packaged IC having a body and upper and lower major surfaces, plural peripheral sides, and leads emergent from at least a first one of the plural peripheral sides of the leaded packaged IC, the leads being connected to the flex circuitry through the plurality of leaded IC pads.

2. The circuit module of claim 1 in which the flex circuitry exhibits a window passing into the flex circuitry from the second side and into which window the semiconductor die is inserted.

3. The circuit module of claim 1 in which the lower major surface of the leaded packaged IC is in contact with the first side of the flex circuitry.

4. The circuit module of claim 3 in which adhesive is disposed between the lower major surface of the leaded packaged IC and the flex circuitry.

5. The circuit module of claim 2 in which the semiconductor die is attached to the first conductive layer.

6. The circuit module of claim 2 in which the semiconductor die is electrically connected to one of the first or second conductive layers with wire bonds.

7. The circuit module of claim 3 in which the semiconductor die is electrically connected to one of the first or second conductive layers.

8. The circuit module of claim 2 in which the leaded packaged IC is a flash memory device.

9. The circuit module of claim 2 in which the semiconductor die is a controller.

10. The circuit module of claim 2 in which the semiconductor die is a controller and the leaded packaged IC is flash memory device.

11. The circuit module of claim 1 in which the semiconductor die is attached to the second conductive layer.

12. The circuit module of claim 1 in which the flex circuitry exhibits a window passing into the flex circuitry from the second side and into which window the semiconductor die is inserted, the window passing through the second conductive layer but not the first conductive layer and the semiconductor die being attached to the first conductive layer and electrically connected to the second conductive layer.

13. The circuit module of claim 12 in which the leaded packaged IC is a flash memory device and the semiconductor die is a controller.

14. The circuit module of claim 2 in which the plurality of leaded IC pads are accessible from the first side of the flex circuitry.

15. A circuit module comprising:
flex circuitry having first and second sides, the flex circuitry having a plurality of leaded IC pads and the second side of the flex circuitry having an array of module contacts, the flex circuitry comprising multiple layers including at least first and second conductive layers and the flex circuitry having a window that passes through the flex circuitry;
a leaded packaged IC having a body and upper and lower major surfaces, plural peripheral sides. and leads emergent from at least a first one of the plural peripheral sides of the leaded packaged IC, the leads being connected to the flex circuitry through the plurality of leaded IC pads and the lower major surface of the leaded packaged IC being in contact with the first side of the flex circuitry; and
a semiconductor die attached the body of the leaded packaged IC and which die projects into the window of the flex circuitry and which semiconductor die is electrically connected to one of the first or second conductive layers of the flex circuitry.

16. The circuit module of claim 15 in which adhesive is disposed between the lower major surface of the leaded packaged IC and the first side of the flex circuitry.

17. The circuit module of claim 15 in which the semiconductor die is electrically connected to the first conductive layer.

18. The circuit module of claim 15 in which the leaded packaged IC is flash memory device and the semiconductor die is a controller.

19. A circuit module comprising:
flex circuitry having first and second sides, the flex circuitry having a plurality of leaded IC pads and the second side of the flex circuitry having an array of module contacts, the flex circuitry comprising multiple layers including at least first and second conductive layers and the flex circuitry having at least one window that passes through the flex circuitry;
a leaded packaged IC having a body and upper and lower major surfaces, plural peripheral sides, and leads emergent from at least a first one of the plural peripheral sides of the leaded packaged IC, the leads being connected to the flex circuitry through the plurality of leaded IC pads; and
a semiconductor die attached the body of the leaded packaged IC and which semiconductor die is electrically connected to one of the first or second conductive layers of the flex circuitry with wire bonds that pass through the at least one window through the flex circuitry.
